(19) United States
(12) Patent Application Publication
(10) Pub. No.: US 2023/0059512 A1
(43) Pub. Date: Feb. 23, 2023

(54) MANUFACTURING METHOD OF ELECTRONIC DEVICE

(71) Applicant: InnoLux Corporation, Miao-Li County (TW)

(72) Inventors: Jia-Yuan CHEN, Miao-Li County (TW); Tsung-Han TSAI, Miao-Li County (TW); Kuan-Feng LEE, Miao-Li County (TW)

(73) Assignee: InnoLux Corporation, Miao-Li County (TW)

(21) Appl. No.: 17/865,417

(22) Filed: Jul. 15, 2022

(30) Foreign Application Priority Data
Aug. 17, 2021 (CN) 202110942356.7

(51) Int. Cl. H01L 33/00; H01L 25/075

(52) U.S. Cl. CPC H01L 33/0095; H01L 25/0753

(57) ABSTRACT

A manufacturing method of an electronic device is provided by the present disclosure, wherein the manufacturing method includes providing a carrier substrate, forming a light emitting module on the carrier substrate, and transferring the light emitting module to a target substrate. The step of forming a light emitting module on the carrier substrate includes transferring a light emitting unit to the carrier substrate, forming a circuit layer on the carrier substrate, and forming a patterned light absorbing layer on the carrier substrate, wherein the patterned light absorbing layer includes an opening through which the light emitting unit is electrically connected to the circuit layer.

### BACKGROUND OF THE DISCLOSURE

### 1. Field of the Disclosure

The present disclosure relates to a manufacturing method of an electronic device, and more particularly to a manufacturing method of an electronic device including a light absorbing layer.

### 2. Description of the Prior Art

Recently, light emitting diodes have been widely used in electronic devices due to their advantages of low power consumption, long lifespan, small size, etc., wherein the light emitting diodes can be miniaturized to improve the display effect of electronic devices. Since the miniaturization of the light emitting diodes may cause abnormal conditions of bonding or electrical connection, the light emitting diodes may be modularized. However, it is difficult to form a light shielding structure or a light absorbing structure that can improve the contrast of the display device after the exist light emitting diode module is bonded to a target substrate, such that the display effect of the display device may be affected. Therefore, to improve the contrast of the electronic device including the light emitting diode module is still an important issue in the present field.

### SUMMARY OF THE DISCLOSURE

A manufacturing method of an electronic device is provided by the present disclosure, such that the light absorbing layer of the electronic device may at least be partially disposed between the circuit layer and the light emitting unit, thereby improving the display effect of the electronic device.

In some embodiments, a manufacturing method of an electronic device is provided by the present disclosure. The manufacturing method includes providing a carrier substrate, forming a light emitting module on the carrier substrate, and transferring the light emitting module to a target substrate. The step of forming a light emitting module on the carrier substrate includes transferring a light emitting unit to the carrier substrate, forming a circuit layer on the carrier substrate, and forming a patterned light absorbing layer on the carrier substrate, wherein the patterned light absorbing layer includes an opening through which the light emitting unit is electrically connected to the circuit layer.

In some other embodiments, a manufacturing method of an electronic device is provided by the present disclosure. The manufacturing method includes providing a carrier substrate, forming a light emitting module on the carrier substrate, dividing the light emitting module into a plurality of sub-light emitting modules on the carrier substrate, and transferring at least one of the plurality of sub-light emitting modules to a target substrate after dividing the light emitting module into a plurality of sub-light emitting modules on the carrier substrate. The step of forming a light emitting module on the carrier substrate includes transferring a plurality of light emitting units to the carrier substrate, and forming a circuit layer on the carrier substrate.

These and other objectives of the present disclosure will no doubt become obvious to those of ordinary skill in the art after reading the following detailed description of the embodiment that is illustrated in the various figures and drawings.

### BRIEF DESCRIPTION OF THE DRAWINGS

FIG. 1 shows a flow chart of a manufacturing method of an electronic device according to a first embodiment of the present disclosure.

FIG. 2 and FIG. 3 schematically illustrate the manufacturing processes of the electronic device according to the first embodiment of the present disclosure.

FIG. 4 and FIG. 5 schematically illustrate the manufacturing processes of an electronic device according to a variant embodiment of the first embodiment of the present disclosure.

FIG. 6 shows a flow chart of a manufacturing method of an electronic device according to a second embodiment of the present disclosure.

FIG. 7 to FIG. 9 schematically illustrate the manufacturing processes of the electronic device according to the second embodiment of the present disclosure.

FIG. 10 schematically illustrates a cross-sectional view of a light emitting module according to a variant embodiment of the second embodiment of the present disclosure.

FIG. 11 schematically illustrates the disposition of a light absorbing layer according to a variant embodiment of the second embodiment of the present disclosure.

FIG. 12 schematically illustrates a cross-sectional view of a light emitting module according to a variant embodiment of the second embodiment of the present disclosure.

FIG. 13 schematically illustrates a cross-sectional view of a light emitting module according to a variant embodiment of the second embodiment of the present disclosure.

FIG. 14 shows a flow chart of a manufacturing method of an electronic device according to a third embodiment of the present disclosure.

FIG. 15 and FIG. 16 schematically illustrate the manufacturing processes of the electronic device according to the third embodiment of the present disclosure.

FIG. 17 schematically illustrates a top view of a light emitting module according to a variant embodiment of the third embodiment of the present disclosure.

FIG. 18 schematically illustrates a bottom view of a circuit layer of a light emitting module according to a variant embodiment of the third embodiment of the present disclosure.

FIG. 19 schematically illustrates the transferring process of a sub-light emitting module according to a variant embodiment of the third embodiment of the present disclosure.

FIG. 20 schematically illustrates the transferring process of a sub-light emitting module according to a variant embodiment of the third embodiment of the present disclosure.

FIG. 21 and FIG. 22 schematically illustrate the manufacturing processes of an electronic device according to a variant embodiment of the third embodiment of the present disclosure.

FIG. 23 schematically illustrates different disposition methods of the supporting substrate shown in FIG. 21.

FIG. 24 schematically illustrates an electronic device according to a variant embodiment of the third embodiment of the present disclosure.

FIG. 25 schematically illustrates an electronic device according to a variant embodiment of the third embodiment of the present disclosure.

FIG. 26 schematically illustrates an electronic device according to a variant embodiment of the third embodiment of the present disclosure.

### DETAILED DESCRIPTION

The present disclosure may be understood by reference to the following detailed description, taken in conjunction with the drawings as described below. It is noted that, for purposes of illustrative clarity and being easily understood by the readers, various drawings of this disclosure show a portion of the electronic device, and certain elements in various drawings may not be drawn to scale. In addition, the number and dimension of each element shown in drawings are only illustrative and are not intended to limit the scope of the present disclosure.

Certain terms are used throughout the description and following claims to refer to particular elements. As one skilled in the art will understand, electronic equipment manufacturers may refer to an element by different names. This document does not intend to distinguish between elements that differ in name but not function.

In the following description and in the claims, the terms “include”, “comprise” and “have” are used in an open-ended fashion, and thus should be interpreted to mean “include, but not limited to . . . ”.

It will be understood that when an element or layer is referred to as being “disposed on” or “connected to” another element or layer, it can be directly on or directly connected to the other element or layer, or intervening elements or layers may be presented (indirectly). In contrast, when an element is referred to as being “directly on” or “directly connected to” another element or layer, there are no intervening elements or layers presented. When an element or a layer is referred to as being “electrically connected” to another element or layer, it can be a direct electrical connection or an indirect electrical connection.

The terms “approximately”, “equal to”, “equal” or “same”, “substantially” or “approximately” are generally interpreted as being within ±20% of the given value, or interpreted as being within ±10%, ±5%, ±3%, ±2%, ±1%, or ±0.5% of the given value.

Although terms such as first, second, third, etc., may be used to describe diverse constituent elements, such constituent elements are not limited by the terms. The terms are used only to discriminate a constituent element from other constituent elements in the specification. The claims may not use the same terms, but instead may use the terms first, second, third, etc. with respect to the order in which an element is claimed. Accordingly, in the following description, a first constituent element may be a second constituent element in a claim.

According to the present disclosure, the width, thickness, height or area of each element or the distance or spacing between the elements may be measured through optical microscopy (OM), scanning electron microscope (SEM), film thickness profilometer (α-step), automatic ellipsometer or other suitable ways, but not limited thereto. In detail, according to some embodiments, the image(s) of the cross-sectional structure(s) of the element(s) to be measured may be obtained through the scanning electron microscope, the width, thickness, height or area of each element or the distance or spacing between the elements can be measured, and the volume of the element(s) can be obtained through any suitable method (such as integral). In addition, any two values or directions used for comparison may have certain errors.

It should be noted that the technical features in different embodiments described in the following can be replaced, recombined, or mixed with one another to constitute another embodiment without departing from the spirit of the present disclosure.

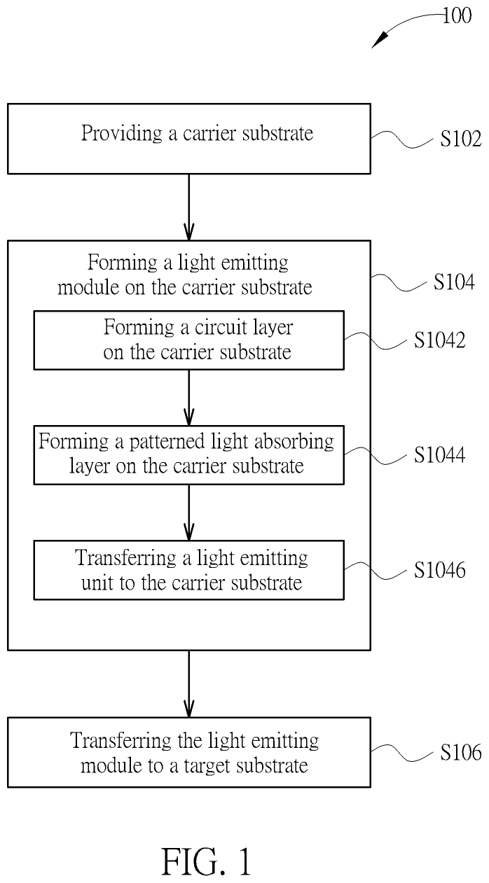

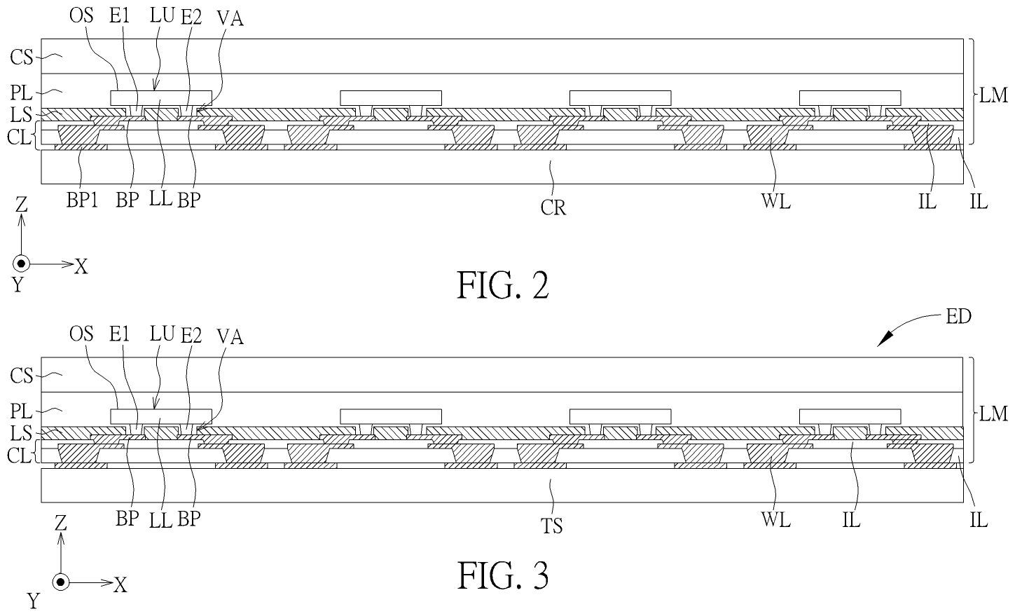

Referring to FIG. 1 to FIG. 3, FIG. 1 shows a flow chart of a manufacturing method of an electronic device according to a first embodiment of the present disclosure, and FIG. 2 to FIG. 3 schematically illustrate the manufacturing processes of the electronic device according to the first embodiment of the present disclosure. The electronic device of the present disclosure (such as the electronic device ED shown in FIG. 3) may for example include a display device that can display static or dynamic images or screens according to the demands and operations of users in the present embodiment, but not limited thereto. The display device may for example be applied to laptops, common displays, tiled displays, vehicle displays, touch displays, television, surveillance cameras, smart phones, tablets, light source modules, light emitting devices or electronic devices of the above-mentioned products, but not limited thereto. The electronic device may further include an antenna device, a sensing device, a tiled device or a transparent display device, but not limited thereto. The electronic device may for example include liquid crystal, light emitting diode (LED), quantum dot (QD), fluorescence, phosphor, other suitable display mediums or the combinations of the above-mentioned materials. The light emitting diode may for example organic light emitting diode (OLED), mini light emitting diode (mini LED), micro light emitting diode (micro LED) or quantum dot light emitting diode (QLED), but not limited thereto. The antenna device may for example be a liquid crystal antenna, but not limited thereto. The tiled device may for example be a tiled display device or a tiled antenna device, but not limited thereto. It should be noted that the electronic device may be combinations of the above-mentioned devices, but not limited thereto. In addition, the electronic device may include a rectangular shape, a circular shape, a polygonal shape, a shape with curved edges or other suitable shapes. The electronic device may include peripheral systems such as driving systems, control systems, light source systems, etc. for supporting the display device, the antenna device or the tiled device. According to the present disclosure, the manufacturing method 100 of the electronic device ED may include the following steps:

S102: providing a carrier substrate CR;

S104: forming a light emitting module LM on the carrier substrate CR;

S106: transferring the light emitting module LM to a target substrate TS.

Wherein the step (S104) of forming a light emitting module LM on the carrier substrate CR may include the following steps:

S1042: forming a circuit layer CL on the carrier substrate CR;

S1044: forming a patterned light absorbing layer LS on the carrier substrate CR;

S1046: transferring a light emitting unit LU to the carrier substrate CR.

Each step of the manufacturing method 100 of the electronic device ED will be detailed in the following.

In the manufacturing method 100 of the electronic device ED of the present embodiment, the step S102 may be performed at first to provide a carrier substrate CR. In the present embodiment, the carrier substrate CR may include rigid materials or flexible materials capable of providing support function, such as glass, polyethylene terephthalate (PET), other suitable materials or the combinations of the above-mentioned materials, but not limited thereto.

Then, the step S104 may be performed to form a light emitting module LM on the carrier substrate CR. As shown in FIG. 2, the light emitting module LM of the present embodiment may include elements and/or layers such as a circuit layer CL, a patterned light absorbing layer LS, light emitting unit(s) LU, a protection layer PL, etc., but not limited thereto. According to the present embodiment, in the step of forming the light emitting module LM on the carrier substrate CR (the step S104), the circuit layer CL may be formed on the carrier substrate CR at first, and then the light emitting units LU are transferred to the carrier substrate CR, but not limited thereto. That is, in the process of forming the light emitting module LM on the carrier substrate CR, the step S1042 (forming the circuit layer CL on the carrier substrate CR) may be performed at first, and then the step S1046 (transferring the light emitting units LU to the carrier substrate CR) may be performed.

In detail, as shown in FIG. 2, in the step S104 (forming the light emitting module LM on the carrier substrate CR) of the present embodiment, the step S1042 may be performed at first to form the circuit layer CL on the carrier substrate CR. It should be noted that “forming the circuit layer CL on the carrier substrate CR” mentioned here may include the condition that the circuit layer CL is formed on the carrier substrate CR and the condition that the circuit layer CL is formed at first and is then disposed on the carrier substrate CR, but the present disclosure is not limited thereto. The circuit layer CL of the present embodiment may for example include a redistribution layer, wherein the redistribution layer may include a plurality of wiring layers WL and a plurality of insulating layers IL. For instance, the circuit layer CL shown in FIG. 2 may for example include two wiring layers WL and two insulating layers IL, and the wiring layers WL may be connected to each other in a vertical direction through the vias of the insulating layers IL, but not limited thereto. The wiring layers WL may include any suitable conductive material, such as metals. The insulating layers IL may include any suitable insulating materials. In addition, as shown in FIG. 2, the wiring layer WL of the circuit layer CL may form a plurality of bonding pads BP located at a side of the circuit layer CL away from the carrier substrate CR. The bonding pads BP of the circuit layer CL may be used to electrically connect the circuit layer CL and the light emitting units LU formed subsequently.

Then, the step S1044 may be performed to form the patterned light absorbing layer LS on the carrier substrate CR and the circuit layer CL. In detail, a light absorbing layer may be blanketly formed on the whole carrier substrate CR and the whole circuit layer CL at first to cover the circuit layer CL, and then, the light absorbing layer may be patterned to form a plurality of openings VA in the light absorbing layer. For example, the patterned light absorbing layer LS may for example be formed through a photolithography process or a printing process in the present embodiment, but not limited thereto. According to the present embodiment, the openings VA may expose at least a portion of the wiring layer WL of the circuit layer CL (for example, the openings VA may expose the bonding pads BP of the circuit layer CL), such that the light emitting units LU formed subsequently may be electrically connected to the bonding pads BP of the circuit layer CL through the openings VA of the patterned light absorbing layer LS. That is, the openings VA of the patterned light absorbing layer LS may substantially correspond to the bonding pads BP of the circuit layer CL. The patterned light absorbing layer LS of the present embodiment may include black matrix, blackened metal materials, other suitable light shielding materials or the combinations of the above-mentioned materials.

After the patterned light absorbing layer LS is formed on the circuit layer CL, the step S1046 may be performed to transfer the light emitting units LU to the carrier substrate CR. Specifically, the light emitting units LU may be formed on a growth substrate (such as a wafer, which is not shown in the figure) at first, and the light emitting units LU may be transferred to the carrier substrate CR, but not limited thereto. The light emitting units LU of the present embodiment may for example include organic light emitting diode (OLED), quantum dot light emitting diode (QLED), light emitting diode (LED), other suitable light emitting elements or the combinations of the above-mentioned elements. The light emitting diode may for example include mini light emitting diode (mini LED) or micro light emitting diode (micro LED), but not limited thereto. In the present embodiment, the light emitting diode is taken as an example of the light emitting units LU for explanation, but the present disclosure is not limited thereto. As shown in FIG. 2, a light emitting unit LU may include a first electrode E1, a second electrode E2 and alight emitting layer LL. One of the first electrode E1 and the second electrode E2 may be the p electrode (or the anode) of the light emitting diode, and another one of the first electrode E1 and the second electrode E2 may be the n electrode (or the cathode) of the light emitting diode. The light emitting layer LL may for example include a p type semiconductor layer, an active layer and an n type semiconductor layer, but not limited thereto. In the present embodiment, after the light emitting unit LU is transferred to the carrier substrate CR, the first electrode E1 and the second electrode E2 of the light emitting unit LU may be disposed in the openings VA of the patterned light absorbing layer LS so as to be in contact with the bonding pads BP of the circuit layer CL. Therefore, the light emitting unit LU may be electrically connected to the circuit layer CL through the openings VA of the patterned light absorbing layer LS. The light emitting unit LU may have a light output surface OS, wherein the light output surface OS may be regarded as the surface of the light emitting unit LU that emits light. For example, the light output surface OS may include the top surface of the light emitting unit LU, but not limited thereto. In some embodiments, the light output surface OS may further include other surfaces of the light emitting unit LU, such as the side surface. After the light emitting unit LU is disposed on the carrier substrate CR, a protection layer PL may optionally be disposed on the carrier substrate CR, wherein the protection layer PL may cover the light emitting unit LU and the layers thereunder to provide the protect function. The protection layer PL may include any suitable transparent insulating material, such that the influence of the protection layer PL on the light emitting effect of the light emitting unit LU may be reduced. The material of the protection layer PL may for example include epoxy resin, silicone, polydimethylsiloxane (PDMS), polyvinyl acetate (PVA), polyvinyl ester, polychloroprene, other suitable packaging materials or organic materials, but not limited thereto. After the protection layer PL is formed, the process of forming the light emitting module LM on the carrier substrate CR may be finished, but not limited thereto.

After the light emitting module LM is formed on the carrier substrate CR, the step S106 may be performed to transfer the light emitting module LM to a target substrate TS, thereby forming the electronic device ED shown in FIG. 3. It should be noted that the light emitting module LM may further optionally include a supporting substrate CS disposed on the protection layer PL in some embodiments, as shown in FIG. 2, but not limited thereto. The supporting substrate CS may provide the support function of the light emitting module LM during the transferring process of the light emitting module LM, such that the damage of the light emitting module LM in the transferring process may be reduced. The material of the supporting substrate CS may refer to the material of the carrier substrate CR mentioned above, and will not be redundantly described. It should be noted that when the supporting substrate CS includes transparent materials, the supporting substrate CS may be remained after the light emitting module LM is transferred to the target substrate TS; and when the supporting substrate CS includes opaque materials, the supporting substrate CS may be removed after the light emitting module LM is transferred to the target substrate TS, but not limited thereto. According to the present embodiment, the target substrate TS may be configured to drive the light emitting units LU to emit light, thereby controlling the display of the electronic device ED. In detail, as shown in FIG. 3, the light emitting unit LU may be electrically connected to the circuit layer CL through the openings VA of the patterned light absorbing layer LS, and the circuit layer CL may be electrically connected to the target substrate TS. For example, the circuit layer CL further includes a plurality of bonding pads BP1, the bonding pads BP1 and the bonding pads BP are respectively located at two sides of the insulating layer IL, and the circuit layer CL may be electrically connected to the elements or the bonding pads (not shown) on the target substrate TS through the bonding pads BP1. Therefore, the target substrate TS may be electrically connected to the light emitting unit LU through the circuit layer CL. The target substrate TS of the present embodiment may for example include any suitable active elements and/or passive elements, such as thin film transistor (TFT), integrated circuit, etc., but not limited thereto. In some embodiments, the target substrate TS may be a metal oxide semiconductor (MOS) substrate.

According to the present embodiment, in the manufacturing method 100, the circuit layer CL, the patterned light absorbing layer LS and the light emitting units LU may be disposed on the carrier substrate CR in sequence. Therefore, the patterned light absorbing layer LS may be disposed between the light emitting units LU and the circuit layer CL in a normal direction (that is, the direction Z) of the electronic device ED (or the normal direction of the target substrate TS), or in other words, at least a portion of the patterned light absorbing layer LS may be located between the light emitting units LU and the circuit layer CL, as shown in FIG. 3. Therefore, in the normal direction (the direction Z) or the top view direction of the electronic device ED, the patterned light absorbing layer LS may cover the circuit layer CL and not cover the light emitting units LU, or in other words, the patterned light absorbing layer LS may not cover the light output surfaces OS of the light emitting units LU. The “top view direction of the electronic device ED” mentioned above may be defined through the light-output side or the user side of the electronic device ED. That is, the top view direction may be the direction in which the user looks at the electronic device ED when using the electronic device ED. According to the present embodiment, since the patterned light absorbing layer LS may cover the circuit layer CL, external light (such as ambient light) entering the circuit layer CL may be reduced, such that the non-display light generated by the reflection of ambient light by the circuit layer CL may be reduced, thereby improving the contrast of the electronic device ED. In addition, since the patterned light absorbing layer LS may not cover the light output surfaces OS of the light emitting units LU, the influence of the patterned light absorbing layer LS on the light emitting effect of the light emitting units LU may be reduced. Furthermore, in the manufacturing method 100 of the present embodiment, since the circuit layer CL may be disposed on the carrier CR prior to the light emitting units LU, the influence of the manufacturing process of the circuit layer CL on the yield of the light emitting units LU may be reduced, thereby improving the yield of the electronic device ED.

It should be noted that the elements and/or layers included in the light emitting module LM of the present embodiment are not limited to the above-mentioned elements and/or layers, and the light emitting module LM may include any suitable element and/or layer according to the demands of the design of the product. More embodiments of the present disclosure will be described in the following. In order to simplify the description, the same layers or elements in the following embodiments would be labeled with the same symbol, and the features thereof will not be redundantly described. The differences between each of the embodiments will be described in detail in the following contents.

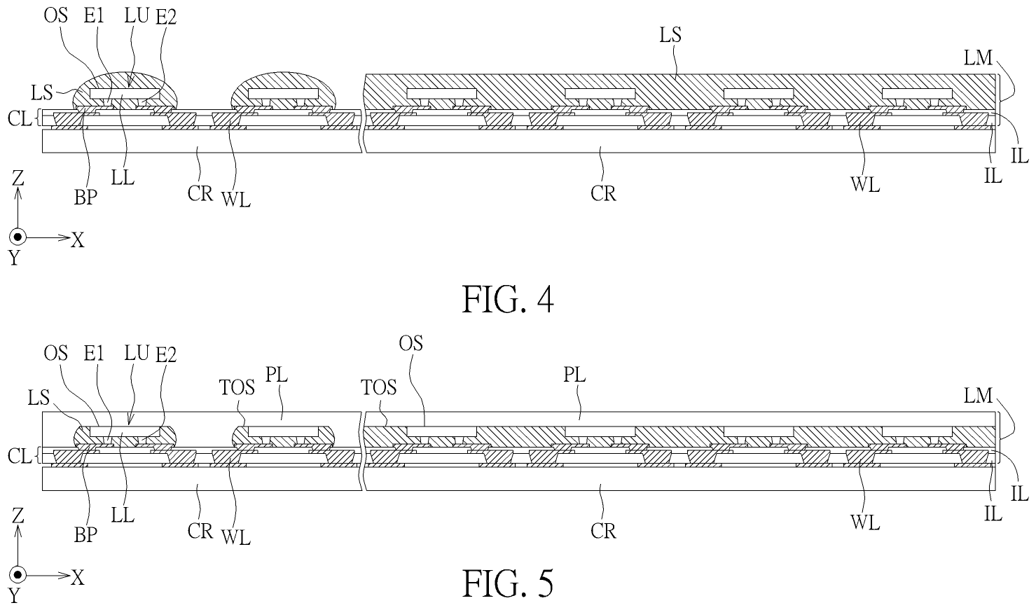

Referring to FIG. 4 and FIG. 5, FIG. 4 and FIG. 5 schematically illustrate the manufacturing processes of an electronic device according to a variant embodiment of the first embodiment of the present disclosure. As shown in FIG. 4, in the present variant embodiment, after the circuit layer CL is formed on the carrier substrate CR, the light emitting units LU may be transferred to the carrier substrate CR to be disposed on the circuit layer CL at first. Therefore, the first electrodes E1 and the second electrodes E2 of the light emitting units LU may be in direct contact with the bonding pads BP of the circuit layer CL in the present variant embodiment, such that the light emitting units LU may be electrically connected to the circuit layer CL, but not limited thereto. After the light emitting units LU are disposed on the circuit layer CL, the patterned light absorbing layer LS may be disposed on the carrier substrate CR subsequently. According to the present variant embodiment, the patterned light absorbing layer LS may for example be disposed on the carrier substrate CR by dispensing or coating, but not limited thereto. In detail, as shown in the left side of FIG. 4, the patterned light absorbing layer LS may for example be disposed on the circuit layer CL and the light emitting unit(s) LU by dispensing the light absorbing-material on the carrier substrate CR corresponding to the disposition position of the light emitting unit(s) LU through a nozzle, thereby covering at least a portion of the light emitting unit(s) LU and the circuit layer CL. Alternatively, as shown in the right side of FIG. 4, the patterned light absorbing layer LS may be disposed on the carrier substrate CR by blanketly coating through a nozzle to cover the light emitting units LU and the circuit layer CL (or cover most of the circuit layer CL).

As shown in FIG. 5, after the patterned light absorbing layer LS is disposed on the carrier substrate CR, a polishing process may be performed to remove at least the portion of the patterned light absorbing layer LS covering the light output surfaces OS of the light emitting units LU, thereby exposing the light output surfaces OS of the light emitting units LU. For example, the light output surfaces OS of the light emitting units LU of the present variant embodiment may for example be the top surfaces of the light emitting units LU. Therefore, the top surfaces of the light emitting units LU may be exposed after the polishing process, and the top surface TOS of the patterned light absorbing layer LS may substantially be aligned with the top surfaces of the light emitting units LU, but not limited thereto. In some embodiments, when the light output surface OS includes other surfaces of the light emitting unit LU, the portions of the patterned light absorbing layer LS covering the other surfaces of the light emitting unit LU may be removed to expose the light output surface OS of the light emitting unit LU. After the polishing process, the protection layer PL may be formed subsequently, and the supporting substrate CS (referring to FIG. 3, not shown in FIG. 4 and FIG. 5) may optionally be formed to form the light emitting module LM. Then, similar to what is shown in FIG. 3, the light emitting module LM may be transferred from the carrier substrate CR to the target substrate TS, thereby forming the electronic device ED.

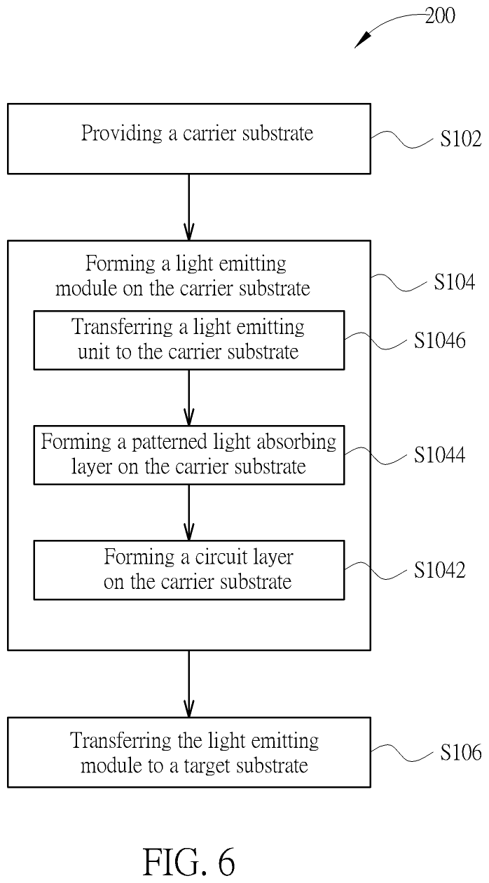

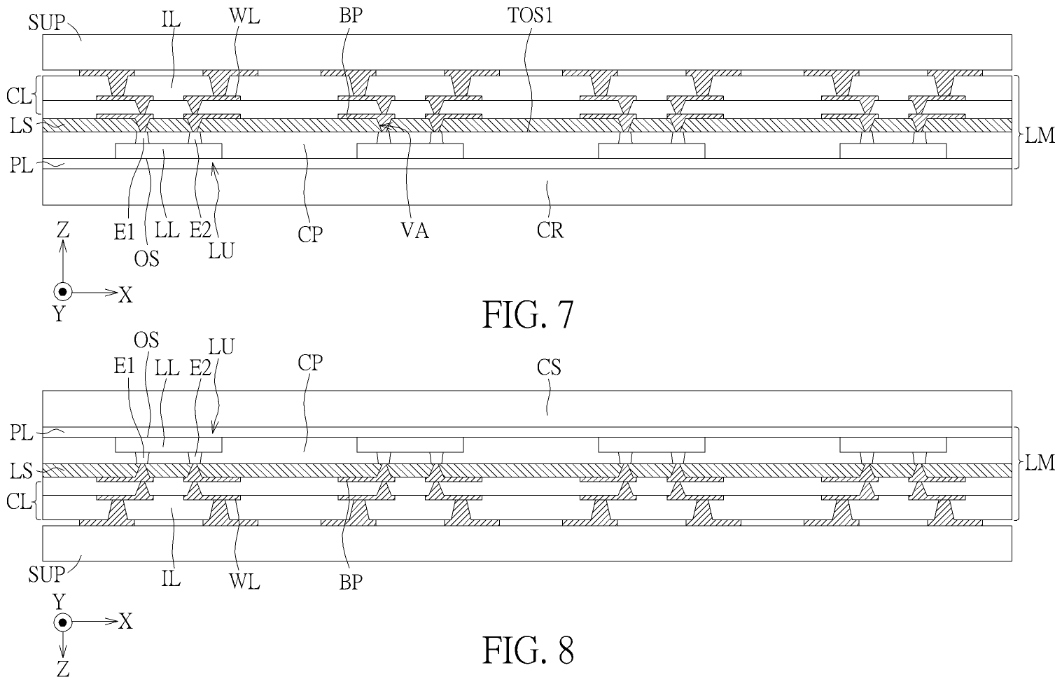

Referring to FIG. 6 to FIG. 9, FIG. 6 shows a flow chart of a manufacturing method of an electronic device according to a second embodiment of the present disclosure, and FIG. 7 to FIG. 9 schematically illustrate the manufacturing processes of the electronic device according to the second embodiment of the present disclosure. As shown in FIG. 6, the manufacturing method 200 of the electronic device ED of the present embodiment may include providing the carrier substrate CR (the step S102), forming the light emitting module LM on the carrier substrate CR (the step S104), and transferring the light emitting module LM to the target substrate TS (the step S106), wherein in the step of forming the light emitting module LM on the carrier substrate CR (the step S104), the light emitting unit LU may be transferred to the carrier substrate CR at first, and then the circuit layer CL may be formed on the carrier substrate CR, but not limited thereto. That is, different from the manufacturing method 100 in the first embodiment, in the step S104 (forming the light emitting module LM on the carrier substrate CR) of the present embodiment, the step S1046 (transferring the light emitting unit LU to the carrier substrate CR) may be performed at first, and then the step S1042 (forming the circuit layer CL on the carrier substrate CR) may be performed.

In detail, after the carrier substrate CR is provided (the step S102), the protection layer PL may be formed on the carrier substrate CR at first, and the light emitting units LU may be disposed on the protection layer PL, but not limited thereto. As shown in FIG. 7, when one light emitting unit LU is disposed on the protection layer PL, the first electrode E1 and the second electrode E2 of the light emitting unit LU may be disposed upward, or in other words, the first electrode E1 and the second electrode E2 may be disposed toward the direction away from the protection layer PL (that is, the direction Z), such that the light emitting unit LU may be electrically connected to the circuit layer CL formed subsequently. At this time, the light output surface OS of the light emitting unit LU may for example face downward, or in other words, the light output surface OS may face the protection layer PL, but not limited thereto. After the light emitting units LU are disposed on the protection layer PL, a cover layer CP may be optionally disposed on the protection layer PL. The cover layer CP may cover the light emitting units LU but at least expose the first electrodes E1 and the second electrodes E2 of the light emitting units LU. That is, the top surface TOS1 of the cover layer CP may not be higher than the top surfaces of the first electrodes E1 and the second electrodes E2 of the light emitting units LU. The cover layer CP may include any suitable insulating material. After the cover layer CP is disposed, the patterned light absorbing layer LS may be formed on the cover layer CP and the light emitting units LU, and the circuit layer CL may be formed on the patterned light absorbing layer LS, thereby forming the light emitting module LM (the step S104). Similarly, the patterned light absorbing layer LS of the present embodiment may include openings VA, such that the circuit layer CL may be electrically connected to the light emitting units LU through the openings VA of the patterned light absorbing layer LS.

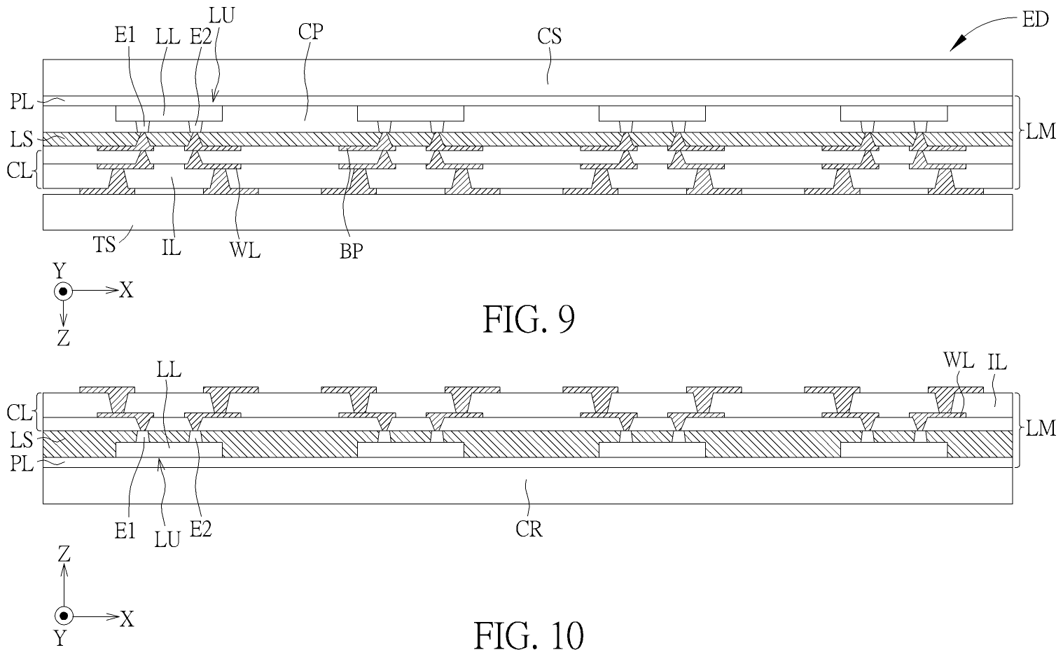

After the light emitting module LM is formed on the carrier substrate CR, the step S106 may be performed to transfer the light emitting module LM to the target substrate TS (shown in FIG. 9). According to the present embodiment, before the light emitting module LM is transferred to the target substrate TS, the light emitting module LM may be transferred to another carrier substrate first, but not limited thereto. In detail, as shown in FIG. 7, the process of transferring the light emitting module LM to the target substrate TS may include disposing the supporting substrate SUP on the light emitting module LM, wherein the supporting substrate SUP may provide the support function during the transferring process of the light emitting module LM. The material of the supporting substrate SUP may refer to the material of the carrier substrate CR mentioned above, and will not be redundantly described. Next, the structure including the carrier substrate CR, the light emitting module LM and the supporting substrate SUP shown in FIG. 7 may be reversed, such that the supporting substrate SUP may be located at the lower part of the structure, and the carrier substrate CR may be removed. Therefore, the light emitting module LM may be transferred from the original carrier substrate CR to another carrier substrate (such as the supporting substrate SUP). As shown in FIG. 8, after the light emitting module LM is transferred to the supporting substrate SUP, the light emitting units LU may be located on the patterned light absorbing layer LS, the patterned light absorbing layer LS may be located on the circuit layer CL, and the light output surfaces OS of the light emitting units LU may face upward. After that, as shown in FIG. 8 and FIG. 9, the supporting substrate CS may be disposed on the protection layer PL of the light emitting module LM, and the light emitting module LM may be transferred from the supporting substrate SUP to the target substrate TS, thereby forming the electronic device ED. When the supporting substrate CS includes transparent materials, the supporting substrate CS may be remained after the light emitting module LM is transferred to the target substrate TS; and when the supporting substrate CS includes opaque materials, the supporting substrate CS may be removed after the light emitting module LM is transferred to the target substrate TS.

Referring to FIG. 10, FIG. 10 schematically illustrates a cross-sectional view of a light emitting module according to a variant embodiment of the second embodiment of the present disclosure. According to the present variant embodiment, the light emitting module LM may not include the above-mentioned cover layer CP that covers the light emitting units LU. In detail, after the protection layer PL and the light emitting unit LU are formed on the carrier substrate CR, the patterned light absorbing layer LS may be directly formed on the protection layer PL and the light emitting units LU, wherein the patterned light absorbing layer LS may cover the light emitting units LU but at least expose the first electrodes E1 and the second electrodes E2 of the light emitting units LU. After that, the circuit layer CL electrically connected to the light emitting units LU may be formed on the patterned light absorbing layer LS, thereby forming the light emitting module LM. The transferring process of the light emitting module LM may refer to the contents in the second embodiment mentioned above, and will not be redundantly described.

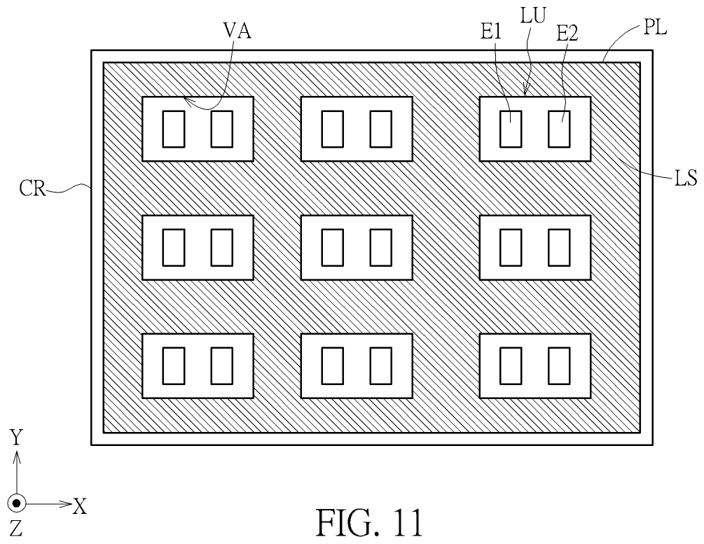

Referring to FIG. 11, FIG. 11 schematically illustrates the disposition of a light absorbing layer according to a variant embodiment of the second embodiment of the present disclosure. One of the differences between the variant embodiment shown in FIG. 10 and the variant embodiment shown in FIG. 11 is the disposition manner of the patterned light absorbing layer LS. According to the present variant embodiment, after the protection layer PL and the light emitting units LU are disposed on the carrier substrate CR, the patterned light absorbing layer LS may be disposed on the protection layer PL along the periphery of the light emitting units LU to form the patterned light absorbing layer LS. Therefore, the patterned light absorbing layer LS may not cover (or not overlap) the light emitting units LU in the normal direction (direction Z) of the carrier substrate CR. For example, the patterned light absorbing layer LS of the present variant embodiment may for example be formed on the carrier substrate CR by a printing process, but not limited thereto. As shown in FIG. 11, since the patterned light absorbing layer LS may be disposed along the periphery of the light emitting units LU, the openings VA of the patterned light absorbing layer LS may substantially correspond to the light emitting units LU respectively.

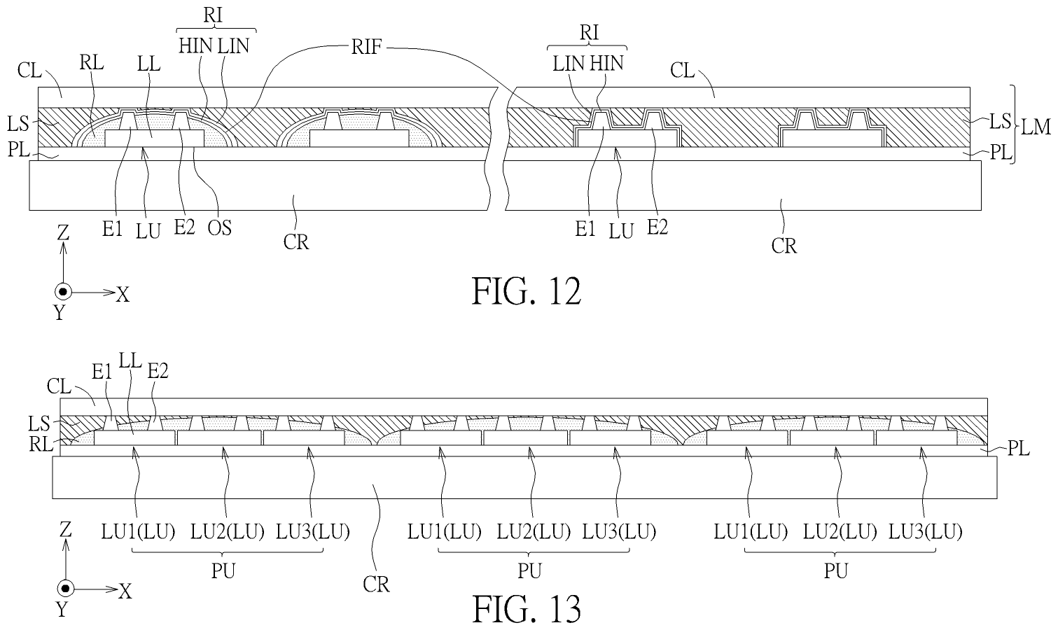

Referring to FIG. 12, FIG. 12 schematically illustrates a cross-sectional view of a light emitting module according to a variant embodiment of the second embodiment of the present disclosure. In order to simplify the figure, the circuit layer CL is shown as a single layer in FIG. 12, but the present variant embodiment is not limited thereto. According to the present variant embodiment, the light emitting module LM may further include an insulating layer RL and a light adjusting layer RI, wherein the insulating layer RL may be disposed on the protection layer PL and the light emitting units LU, and the light adjusting layer RI may be disposed on the insulating layer RL, but not limited thereto. The material of the insulating layer RL may for example include resin or other suitable transparent insulating materials, but the present disclosure is not limited thereto. In detail, as shown in FIG. 12, after the protection layer PL and the light emitting units LU are formed on the carrier substrate CR, an insulating material may be dropped at the positions corresponding to the disposition positions of the light emitting units LU to form the insulating layer RL on the light emitting units LU, wherein the insulating layer RL may cover the light emitting units LU or at least cover the light emitting layers LL of the light emitting units LU, but not limited thereto. According to the present variant embodiment, the insulating layer RL may reduce the possibility of total reflection of the light emitted by the light emitting units LU at the surface of the light emitting units LU. After the insulating layer RL is formed, the light adjusting layer RI may be formed on the insulating layer RL, but not limited thereto. In some embodiments, as shown in FIG. 12, when the insulating layer RL partially covers the first electrodes E1 and the second electrodes E2 of the light emitting units LU, the light adjusting layer RI may substantially be formed conformally on the insulating layer RL, the first electrodes E1 and the second electrodes E2. According to the present variant embodiment, the light adjusting layer RI may include a stacked structure formed by alternately stacking insulating layer (s) with a high refractive index and insulating layer(s) with a low refractive index, and the interface between the insulating layer with high refractive index and the insulating layer with low refractive index may form a reflective interface. For example, the light adjusting layer RI shown in FIG. 12 may for example be formed of one high-refractive-index insulating layer HIN and one low-refractive-index insulating layer LIN, and a reflective interface RIF may be located therebetween, but not limited thereto. In some embodiments, the light adjusting layer RI may be a five-layer structure or a multi-layer structure formed by alternately stacking high-refractive-index insulating layers HIN and low-refractive-index insulating layers LIN, and the light adjusting layer RI may include a plurality of reflective interfaces RIF. In the present variant embodiment, the difference between the refractive indices of the high-refractive-index insulating layer HIN and the low-refractive-index insulating layer LIN may be greater than 0.5. For example, the high-refractive-index insulating layer HIN may include insulating materials with a refractive index greater than 2.1 (such as nitrides), and the low-refractive-index insulating layer LIN may include insulating materials with a refractive index lower than 1.5 (such as oxides), but not limited thereto. According to the present variant embodiment, since the reflectivity of light at the reflective interface RIF may be improved, the light emitting effect of the light emitting unit LU may be improved accordingly. After the reflective interface RIF is disposed, the patterned light absorbing layer LS and the circuit layer CL may then be disposed on the protection layer PL and the light adjusting layer RI to form the light emitting module LM, and the light emitting module LM may be transferred to the target substrate (not shown) by a transferring process to form the electronic device of the present disclosure. It should be noted that although it is not shown in FIG. 12, the portion of the light adjusting layer RI corresponding to the first electrode E1 and the second electrode E2 of the light emitting unit LU may include openings, such that the circuit layer CL may be electrically connected to the light emitting unit LU through the openings of the light adjusting layer RI. In addition, in some embodiments, as shown in the right side of FIG. 12, the light emitting module LM may include the light adjusting layer RI but not include the insulating layer RL, and the light adjusting layer RI may be formed conformally on the light emitting unit LU, but not limited thereto. The feature mentioned in the present variant embodiment that the light emitting module LM includes the insulating layer RL and/or the light adjusting layer RI may be applied to each of the embodiments and variant embodiments of the present disclosure.

Referring to FIG. 13, FIG. 13 schematically illustrates a cross-sectional view of a light emitting module according to a variant embodiment of the second embodiment of the present disclosure. In order to simplify the figure, the circuit layer CL is shown as a single layer in FIG. 13, but the present variant embodiment is not limited thereto. In the present variant embodiment, the light emitting module LM may include a light emitting unit LU1, a light emitting unit LU2 and a light emitting unit LU3, wherein the light emitting unit LU1, the light emitting unit LU2 and the light emitting unit LU3 may respectively emit lights of different colors, and the lights of different colors may be mixed to form the required light. Therefore, as shown in FIG. 13, one light emitting unit LU1, one light emitting unit LU2, and one light emitting unit LU3 may be disposed adjacent to each other on the protection layer PL and form a pixel unit PU. The light emitting unit LU1, the light emitting unit LU2 and the light emitting unit LU3 may respectively emit red light, blue light and green light, and the lights may be mixed to form white light, but not limited thereto. According to the present variant embodiment, the light emitting module LM may include the insulating layer RL, wherein the insulating layer RL may be disposed corresponding to the pixel units PU. The disposition method of the insulating layer RL may refer to the above-mentioned contents, and will not be redundantly described. In detail, as shown in FIG. 13, each of the pixel units PU in the light emitting module LM may for example correspond to one insulating layer RL, wherein the insulating layer RL may at least cover the light emitting layers LL of the light emitting unit LU1, the light emitting unit LU2 and the light emitting unit LU3 of the light emitting unit LU corresponding to the insulating layer RL. Therefore, the color mixing effect of the light emitting unit LU1, the light emitting unit LU2 and the light emitting unit LU3 in the same pixel unit PU may be improved by the insulating layer RL, thereby improving the display effect of the light emitting module LM. After the insulating layer RL is disposed, the patterned light absorbing layer LS and the circuit layer CL may then be formed to form the light emitting module LM. After that, the light emitting module LM may be transferred to the target substrate TS through a transferring process to form the electronic device ED. In an embodiment, the light adjusting layer RI may be formed on the insulating layer RL, but not limited thereto.

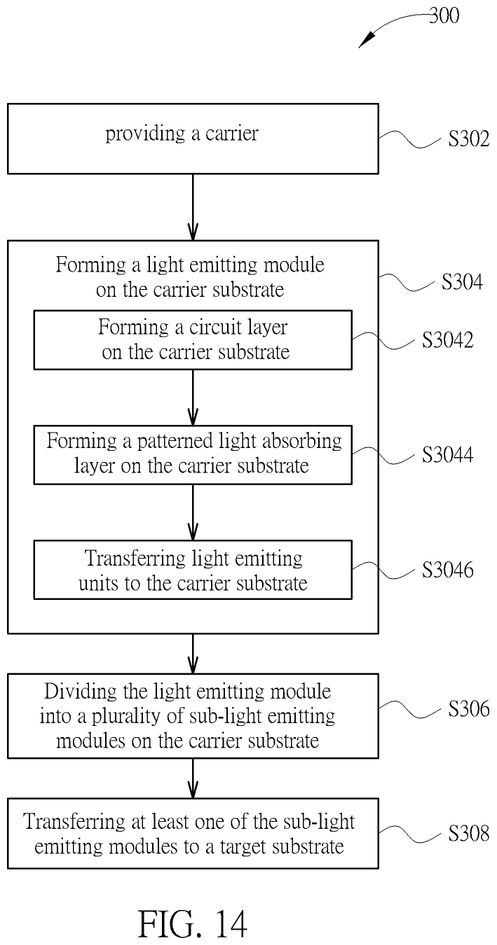

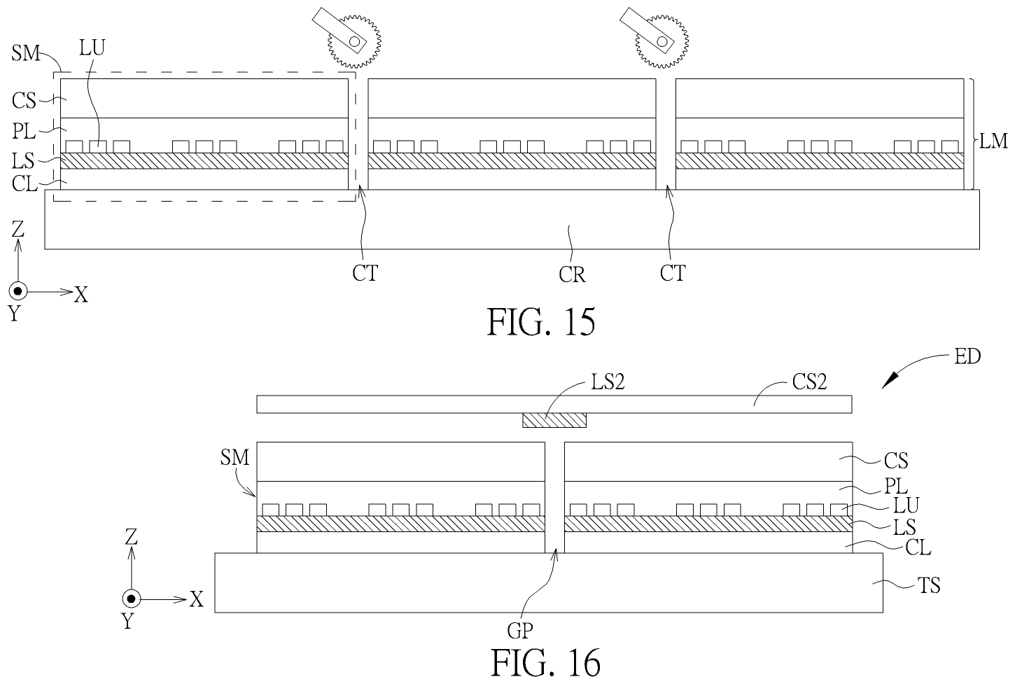

Referring to FIG. 14 to FIG. 16, FIG. 14 shows a flow chart of a manufacturing method of an electronic device according to a third embodiment of the present disclosure, and FIG. 15 and FIG. 16 schematically illustrate the manufacturing processes of the electronic device according to the third embodiment of the present disclosure. It should be noted that in order to simplify the figures, the light emitting unit is just simply shown in FIG. 15, 16 and the following figures, and the detailed structure of the light emitting unit LU is not shown. As shown in FIG. 14, the manufacturing method 300 of the electronic device ED of the present embodiment includes the following steps:

S302: providing a carrier CR

S304: forming a light emitting module LM on the carrier substrate CR

S306: dividing the light emitting module LM into a plurality of sub-light emitting modules SM on the carrier substrate CR

S308: transferring at least one of the sub-light emitting modules SM to a target substrate TS

wherein the step of forming a light emitting module LM on the carrier substrate CR (the step S304) may include the following steps:

S3042: forming a circuit layer CL on the carrier substrate CR

S3044: forming a patterned light absorbing layer LS on the carrier substrate CR

S3046: transferring light emitting units LU to the carrier substrate CR

Each step of the manufacturing method 300 of the electronic device ED will be detailed in the following.

In the manufacturing method 300 of the electronic device ED of the present embodiment, the step S302 and the step S304 may be performed at first to provide the carrier substrate CR and form the light emitting module LM on the carrier substrate CR. The details of the step S302 and the step S304 may respectively refer to the step S102 and the step S104 in the above-mentioned embodiments, and will not be redundantly described. In addition, as shown in FIG. 15, in the process of forming the light emitting module LM on the carrier substrate CR (the step S304), the circuit layer CL may for example be formed on the carrier substrate CR at first, and then the light emitting units LU are transferred to the carrier substrate CR, but not limited thereto. That is, the step S3042 may be performed at first, and then the step S3046 may be performed in the present embodiment. The detailed structure of the light emitting module LM of the present embodiment may for example refer to the structure of the light emitting module LM shown in FIG. 2, but not limited thereto.

After the light emitting module LM is formed on the carrier substrate CR, the step S306 may be performed subsequently to divide the light emitting module LM into a plurality of sub-light emitting modules SM on the carrier substrate CR. For example, the light emitting module LM may be divided into the plurality of sub-light emitting modules SM by wheel cutting, laser cutting, chemical etching, etc., but not limited thereto. In detail, as shown in FIG. 15, after the light emitting module LM is formed, cutting lines CT may be defined on the light emitting module LM, and the light emitting module LM may be cut along the defined cutting lines CT to be divided into the plurality of sub-light emitting modules SM. In some embodiments, the light emitting module LM may be divided into the plurality of sub-light emitting modules SM by wheel cutting, wherein the light emitting module LM may be cut by a plurality of cutting wheels simultaneously during the wheel cutting process. In some embodiments, the light emitting module LM may be divided into the plurality of sub-light emitting modules SM by a laser cutting process. In some embodiments, the light emitting module LM may be divided into the plurality of sub-light emitting modules SM by a photolithography-etching process. It should be noted that the supporting substrates CS shown in FIG. 15 may be disposed respectively corresponding to the sub-light emitting modules SM after the sub-light emitting modules SM are formed in some embodiments. Or, in some embodiments, the supporting substrate CS may be disposed on the light emitting module LM at first, and the supporting substrate CS and the light emitting module LM may be cut together. It should be noted that when the supporting substrate CS shown in FIG. 15 includes opaque materials, the supporting substrate CS may be removed from the light emitting module LM.

After the sub-light emitting modules SM are formed through the above-mentioned methods, the step S308 may be performed subsequently to transfer at least one of the sub-light emitting modules SM to the target substrate TS. Specifically, according to the demands of the design of the electronic device ED, any number of sub-light emitting modules SM may be transferred from the carrier substrate CR to the target substrate TS. For example, FIG. 16 shows the structure that two sub-light emitting modules SM are transferred to the target substrate TS, but not limited thereto. In the present embodiment, after the sub-light emitting modules SM are transferred to the target substrate TS, a cover substrate CS2 may be disposed on the other side of the sub light-emitting modules SM opposite to the target substrate TS, wherein the cover substrate CS2 may include a light shielding layer LS2 disposed at the side of the cover substrate CS2 facing the sub-light emitting modules SM. The material of the cover substrate CS2 may refer to the supporting substrate CS in the above-mentioned embodiments, and will not be redundantly described. The material of the light shielding layer LS2 may for example include light absorbing materials, but the present disclosure is not limited thereto. In some embodiments, the material of the light shielding layer LS2 may for example include black matrix, blackened metal materials, other suitable light shielding materials or the combinations of the above-mentioned materials. According to the present embodiment, the light shielding layer LS2 may be disposed corresponding to the gaps GP between the sub-light emitting modules SM on the cover substrate CS2. Therefore, when the cover substrate CS2 is disposed on the sub-light emitting modules SM, at least a portion of the light shielding layer LS2 may be filled into the gaps GP between the sub-light emitting modules SM, but not limited thereto. After the cover substrate CS2 is disposed on the sub-light emitting modules SM, the electronic device ED of the present embodiment may be formed. It should be noted that when the cover substrate CS2 includes transparent materials, the cover substrate CS2 may not be removed from the electronic device ED; and when the cover substrate CS2 includes opaque materials, the cover substrate CS2 may be removed from the electronic device ED, and the light shielding layer LS2 filled into the gaps GP may be remained.

According to the manufacturing method 300 of the electronic device ED of the present embodiment, the light emitting module LM may be divided into sub-light emitting modules SM with smaller size through a separating process before being transferred to the target substrate TS. Compared with the light emitting module LM with greater size, the sub-light emitting modules SM of the present embodiment may be easily transferred, thereby reducing the difficulty of the transferring process. In addition, as mentioned above, since the patterned light absorbing layer LS of the electronic device ED may be disposed between the circuit layer CL and the light emitting units LU, the non-display light generated by the reflection of the ambient light by the circuit layer CL may be reduced, thereby improving the contrast of the electronic device ED. Moreover, since the electronic device ED may include the light shielding layer LS2 filled into the gaps GP between the sub-light emitting modules SM to reduce the ambient light entering the gaps GP, the non-display light generated by the reflection of ambient light by the circuit layer CL exposed by the gaps GP may be reduced, thereby improving the contrast of the electronic device ED.

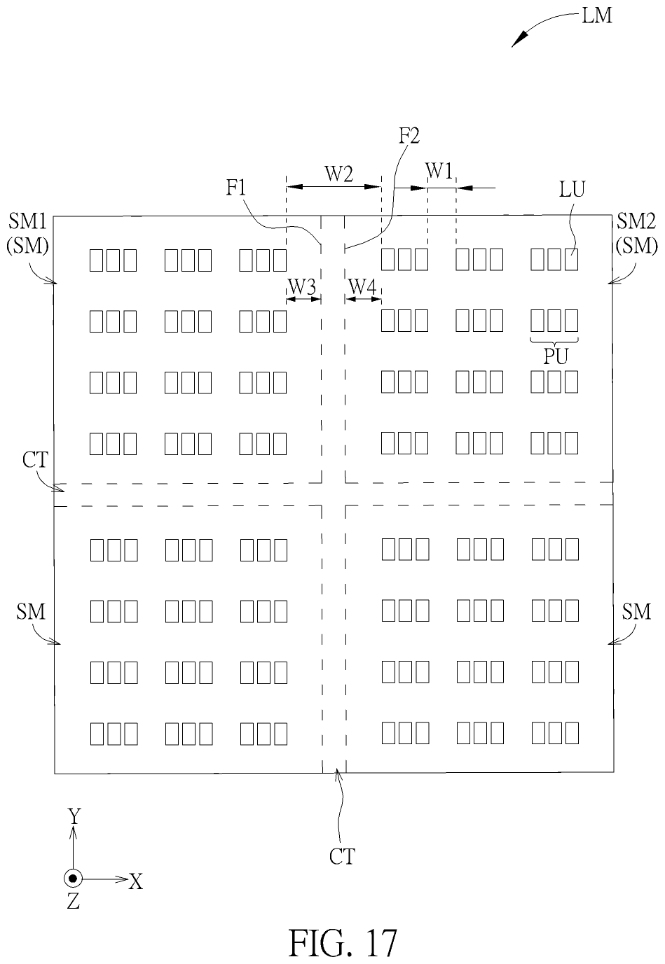

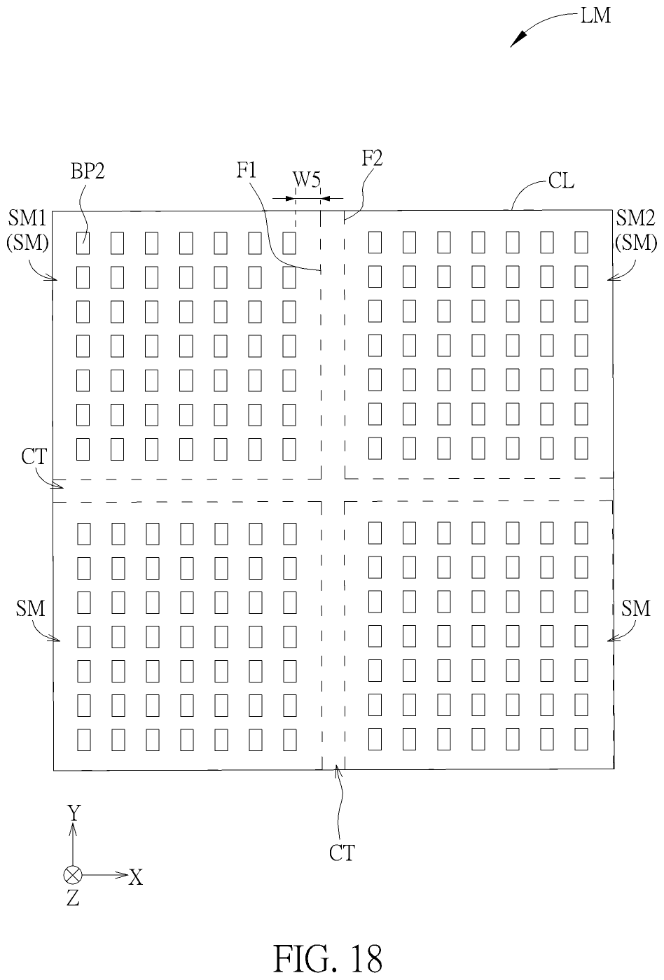

Referring to FIG. 17 and FIG. 18, FIG. 17 schematically illustrates a top view of a light emitting module according to a variant embodiment of the third embodiment of the present disclosure, and FIG. 18 schematically illustrates a bottom view of a circuit layer of a light emitting module according to a variant embodiment of the third embodiment of the present disclosure. As shown in FIG. 17, the light emitting module LM of the present variant embodiment may for example include a plurality of pixel units PU, wherein each of the pixel units PU may include three light emitting units LU respectively emit lights of different colors, but not limited thereto. The feature of the pixel unit PU may refer to the above-mentioned contents, and will not be redundantly described. According to the present variant embodiment, during the process of forming the pixel units PU (or the light emitting units LU) of the light emitting module LM, the distance between the pixel units PU may be designed, such that the distance between two pixel units PU respectively located at two opposite sides of the cutting line CT may be greater than the distance between two pixel units PU not located at two opposite sides of the cutting line CT. For example, the light emitting module LM may include two cutting lines CT respectively extend along the direction X and the direction Y, and taking the cutting line CT extending along the direction Y as an example, a distance W2 may be included between the two pixel units PU respectively located at two opposite sides of the cutting line CT, a distance W1 may be included between the two pixel units PU which are not located at two opposite sides of the cutting line CT, wherein the distance W2 may be greater than the distance W1, but not limited thereto. In some embodiments, the number and extending direction of the cutting line CT may be determined according to the demands of the design of the product. It should be noted that “the distance between the two pixel units PU” mentioned above may for example be defined as the minimum distance between the light emitting unit LU in a pixel unit PU and the light emitting unit LU in another pixel unit PU, but not limited thereto. According to the present variant embodiment, since the distance between the pixel units PU at two opposite sides of the cutting line CT may be greater, the possibility of damage of the light emitting units LU during the cutting process may be reduced, thereby improving the yield of the electronic device ED.

In addition, as shown in FIG. 17, after the cutting process is performed along the two cutting lines CT, the light emitting module LM may be divided into four sub-light emitting modules SM. Taking the sub-light emitting modules SM1 and the sub-light emitting modules SM2 as an example, the edge F1 of the sub-light emitting modules SM1 and the edge F2 of the sub-light emitting modules SM2 may be formed by cutting the light emitting module LM through the cutting line CT along the direction Y, but not limited thereto. According to the present variant embodiment, a distance W3 may be included between the light emitting unit LU in the sub-light emitting modules SM1 closest to the edge F1 and the edge F1, and a distance W4 may be included between the light emitting unit LU in the sub-light emitting modules SM2 closest to the edge F2 and the edge F2, wherein the sum of the distance W3 and the distance W4 may be lower than the distance W2 between the two pixel units PU respectively located at two opposite sides of the cutting line CT. Since the distance W3 and/or the distance W4 may be included between the sub-light emitting modules SM1 and the edge F1 and/or the sub-light emitting modules SM2 and the edge F2, the possibility of damage to the light emitting units LU due to being too close to the edge of the sub-light emitting module SM1 and/or the sub-light emitting module SM2 may be reduced. In addition, the distance W3 and the distance W4 may be adjusted in the present variant embodiment, such that the distance W3 and the distance W4 may substantially be the same, but not limited thereto. That is, the distance W3 and the distance W4 may respectively be lower than half of the distance W2 (i.e. W3, W4<½W2). For example, after the cutting process, the values of the distance W3 and the distance W4 may be adjusted through a side surface polishing process, but not limited thereto. By making the distance W3 and the distance W4 substantially the same, when the sub-light emitting module SM1 and the sub-light emitting module SM2 are applied to the tiled display device, the influence on the display effect of the tiled display device caused by the structural difference of the sub-light emitting modules may be reduced.

Moreover, as shown in FIG. 18, FIG. 18 shows the structure of the bonding pads BP2 (may refer to the bonding pad BP1 shown in FIG. 2, too) of the circuit layer CL of the light emitting module LM, wherein the bonding pads BP2 may be configured to electrically connecting the circuit layer CL to the target substrate. According to the present variant embodiment, taking the sub-light emitting module SM1 as an example, a distance W5 may be included between the bonding pads BP2 of the sub-light emitting module SM1 closest to the edge F1 and the edge F1, wherein the distance W5 may be greater than the distance between the light emitting unit LU closest to the edge F1 and the edge F1 (that is, the distance W3 mentioned above, as shown in FIG. 17), but not limited thereto. By making the distance W5 greater than the distance W3, the bonding yield of the sub-light emitting module SM1 may be improved, thereby improving the yield of the electronic device ED.

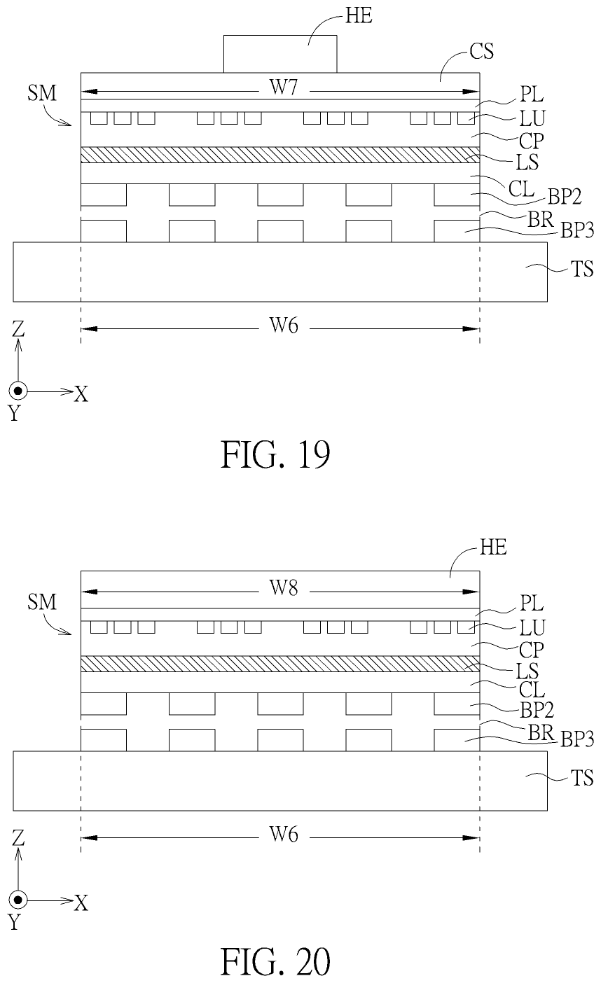

Referring to FIG. 19 and FIG. 20, FIG. 19 schematically illustrates the transferring process of a sub-light emitting module according to a variant embodiment of the third embodiment of the present disclosure, and FIG. 20 schematically illustrates the transferring process of a sub-light emitting module according to a variant embodiment of the third embodiment of the present disclosure. As shown in FIG. 19 and FIG. 20, a transfer head HE may be disposed on the sub-light emitting module SM before the sub-light emitting module SM is transferred, and the sub-light emitting module SM may be transferred from the carrier substrate CR to the target substrate TS through the transfer head HE. At this time, the bonding pads BP2 of the circuit layer CL may be bonded to the bonding pads BP3 on the target substrate TS, and a bonding region BR may for example be formed. The bonding region BR may for example be defined as the region enclosed by the outer edges of the outermost bonding pads BP2 in the circuit layer CL, but not limited thereto. According to the present embodiment, as shown in FIG. 19, the bonding region BR may have a bonding width W6 in a direction (such as the direction X) parallel to the target substrate TS, and the supporting substrate CS may have a width W7 in the same direction, wherein the width W6 and the width W7 may be the same, but not limited thereto. That is, the supporting substrate CS may be disposed corresponding to the bonding region BR in the present embodiment. In some embodiments, the bonding width W6 and the width of the sub-light emitting module SM may substantially be the same. In some embodiments, the bonding width W6 may be lower than the width of the sub-light emitting module SM. According to the present embodiment, since the width W7 of the supporting substrate CS of the sub-light emitting module SM may be the same as the bonding width W6 of the bonding region BR, the deformation of the sub-light emitting module SM caused by stress during the transfer process may be reduced, thereby improving the yield of the electronic device ED.

Or, as shown in FIG. 20, the sub-light emitting module SM may not include the supporting substrate CS in some embodiments. In addition, the transfer head HE disposed on the sub-light emitting module SM may have a width W8, wherein the width W8 may substantially be the same as the bonding width W6 of the bonding region BR, but not limited thereto. That is, the transfer head HE may be disposed corresponding to the bonding region BR. Since the width W8 of the transfer head HE may be the same as the bonding width W6 of the bonding region BR, the deformation of the sub-light emitting module SM caused by stress during the transfer process may be reduced, thereby improving the yield of the electronic device ED.

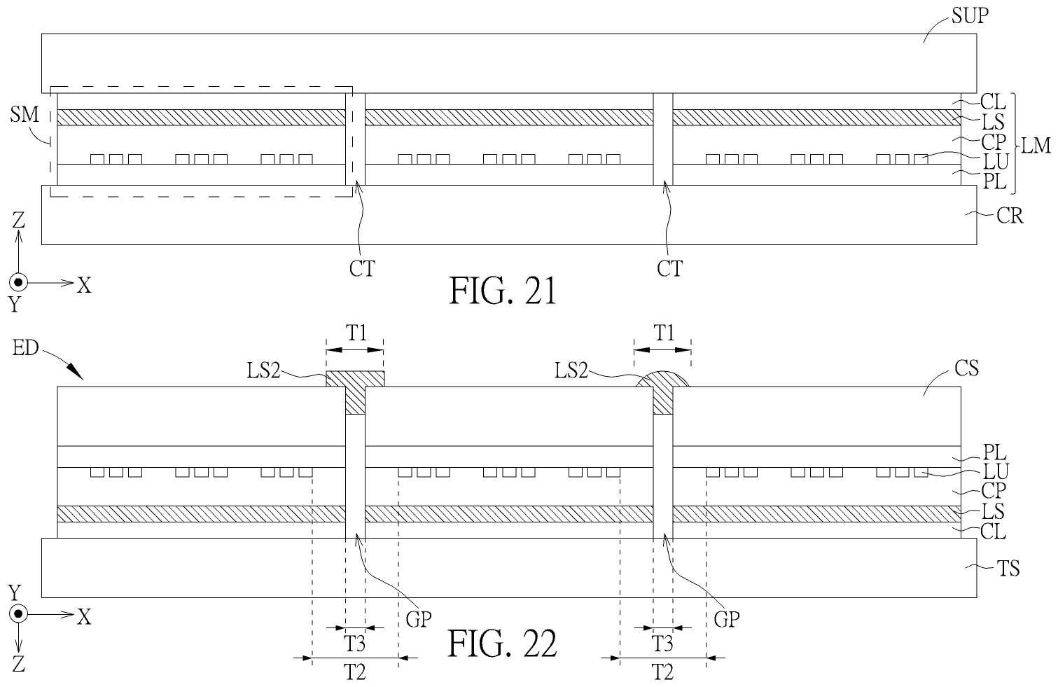

Referring to FIGS. 21 and 22, FIG. 21 and FIG. 22 schematically illustrate the manufacturing processes of an electronic device according to a variant embodiment of the third embodiment of the present disclosure. The manufacturing method of the electronic device ED of the present variant embodiment may refer to the method 300 shown in FIG. 14, but different from the method 300, in the step S304 (forming the light emitting module LM on the carrier substrate CR) of the present variant embodiment, the step S3046 (transferring the light emitting unit LU to the carrier substrate CR) may be performed at first, and then the step S3042 (forming the circuit layer CL on the carrier substrate CR) may be performed. In detail, the light emitting unit LU, the patterned light absorbing layer LS and the circuit layer CL may be formed on the carrier substrate CR in sequence to form the light emitting module LM, and then, the light emitting module LM may be divided into a plurality of sub-light emitting modules SM along the cutting lines CT (the step S306), and the supporting substrate SUP may be disposed on the sub-light emitting modules SM to form the structure shown in FIG. 21. After that, referring the processes shown in FIG. 7 to FIG. 9, the structure shown in FIG. 21 may be reversed, the carrier substrate CR may be removed, the supporting substrate CS may be disposed, and the sub-light emitting modules SM may be transferred from the supporting substrate SUP to the target substrate TS, thereby forming the electronic device ED, but not limited thereto. It should be noted that the disposition method of the supporting substrate SUP of the present variant embodiment is not limited to what is shown in FIG. 21, and the disposition methods of the supporting substrate SUP of other embodiments will be introduced in the following. According to the present variant embodiment, the electronic device ED may further include a light shielding layer LS2 disposed corresponding to the gaps GP between the sub-light emitting modules SM, wherein the light shielding layer LS2 may at least be partially filled into the gaps GP. The light shielding layer LS2 may have any suitable shape, and the present variant embodiment is not limited thereto. As shown in FIG. 22, the gap GP may have a width T3, the minimum distance between the light emitting units LU in the adjacent two sub-light emitting modules SM may be the distance T2, and the light shielding layer LS2 may have a maximum width T1. In the present variant embodiment, the maximum width T1 may be greater than the width T3 and lower than the distance T2 (that is, width T3<maximum width T1<distance T2), but not limited thereto. By making the maximum width T1 greater than the width T3, the light shielding layer LS2 may effectively seal the gaps GP, thereby reducing the possibility of the ambient light entering the gaps GP. In addition, by making the maximum width T1 lower than the distance T2, the influence of the light shielding layer LS2 on the light output of the light emitting units LU may be reduced.

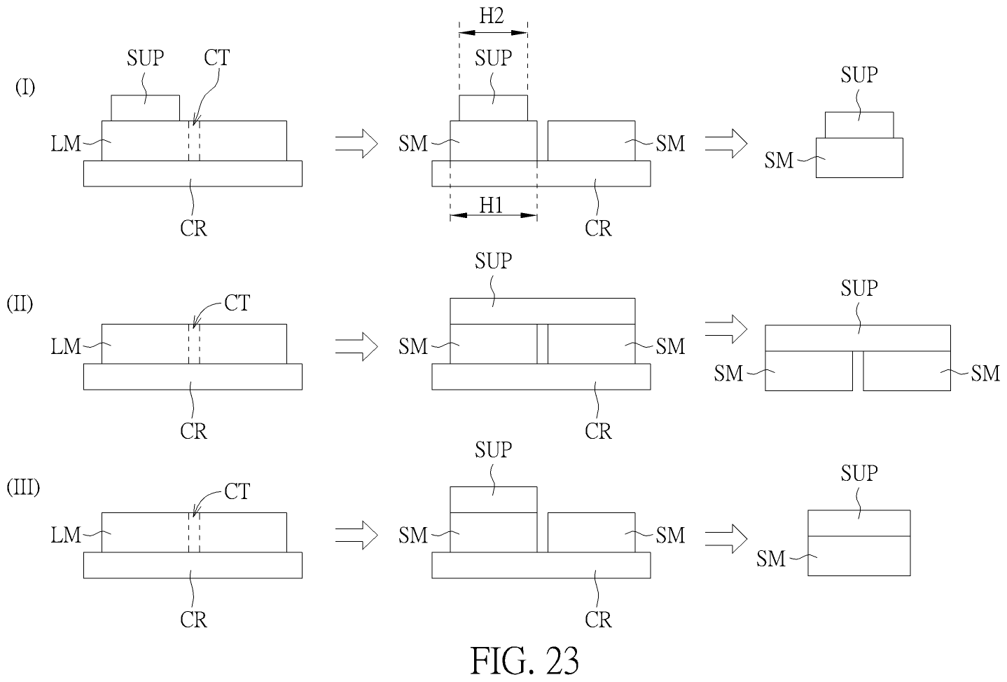

Referring to FIG. 23, FIG. 23 schematically illustrates different disposition methods of the supporting substrate shown in FIG. 21. As shown in FIG. 23, the supporting substrate SUP may be disposed on the sub-light emitting modules SM through various methods. First, as shown in method (I), before dividing the light emitting module LM into the sub-light emitting modules SM, the supporting substrate SUP may be provided on the carrier substrate CR and disposed on the light emitting module LM. In the method (I), the supporting substrate SUP may for example be disposed corresponding to the sub-light emitting modules SM to be formed, wherein the supporting substrate SUP may not overlap the cutting lines CT. It should be noted that although it is not shown in method (I), a plurality of supporting substrates SUP may be disposed on the light emitting module LM, and the supporting substrates SUP may be disposed corresponding to two or more sub-light emitting modules SM to be formed. After the supporting substrate SUP is formed, a cutting process may be performed to divide the light emitting module LM into a plurality of sub-light emitting modules SM, and at least one of the sub-light emitting modules SM corresponding to the supporting substrate SUP may be transferred to the target substrate TS. Before transferring the sub-light emitting modules SM, the structure may for example be reversed, such that the supporting substrate SUP may be located at the lower side, but not limited thereto. Since the supporting substrate SUP may not be disposed corresponding to the cutting lines CT in method (I), the influence of the supporting substrate SUP on the cutting process may be reduced. In another aspect, since the supporting substrate SUP in the method (I) may not be cut in the cutting process, it is not a consumable. Therefore, the production cost may be reduced. In addition, in method (I), the width H2 of the supporting substrate SUP may for example be lower than the width H1 of the sub-light emitting module SM, such that the position of the cutting lines CT may be reserved, but not limited thereto. Therefore, the damage of the supporting substrate SUP during the cutting process may be reduced.

Or, as shown in method (II) and (III), the cutting process may be performed at first, and then the supporting substrate SUP may be disposed on the sub-light emitting modules SM. In method (II), the supporting substrate SUP may be disposed corresponding to more than one or all of the sub-light emitting modules SM, and the plurality of sub-light emitting modules SM may be transferred through the supporting substrate SUP. In method (III), the supporting substrate SUP may be disposed corresponding to one sub-light emitting module SM, and the one sub-light emitting module SM may be transferred through the supporting substrate SUP. Before, the sub-light emitting module SM is transferred, the structure may for example be reversed, such that the supporting substrate SUP may be located at the lower side, but not limited thereto. For example, in the embodiment shown in FIG. 21, the supporting substrate SUP is disposed through the method (II), but the present disclosure is not limited thereto. In some embodiments, the supporting substrate SUP shown in FIG. 21 may be disposed through the method (II) or method (III). Since the cutting process is performed at first in method (II) and method (III), and then the supporting substrate SUP is disposed, the influence of the supporting substrate SUP on the cutting process may be reduced. In addition, since the supporting substrate SUP in the method (II) and method (III) may not be cut in the cutting process, it is not a consumable. Therefore, the production cost may be reduced. It should be noted that the disposition methods of the support substrate SUP shown in FIG. 23 may be applied to the supporting substrate CS shown in FIG. 15, but not limited thereto. That is, the supporting substrate CS shown in FIG. 15 may be disposed on the carrier substrate CR through the method (I), the method (II) or the method (III).

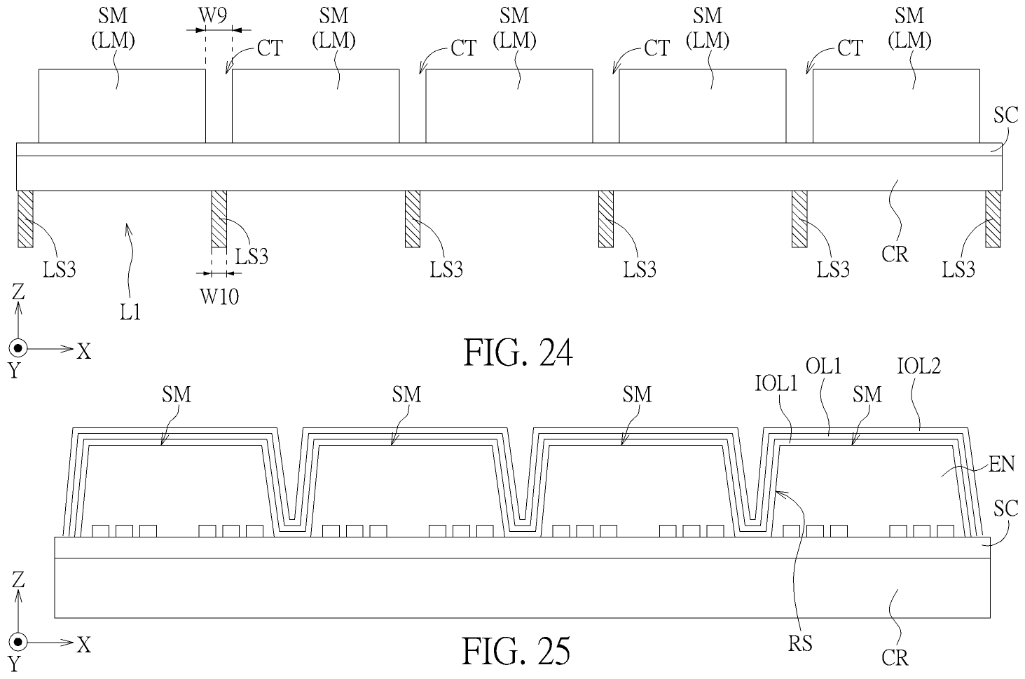

Referring to FIG. 24, FIG. 24 schematically illustrates an electronic device according to a variant embodiment of the third embodiment of the present disclosure. In order to simplify the figure, FIG. 24 just simply shows the sub-light emitting modules SM, and the detailed structure of the sub-light emitting module SM may refer to the contents in the above-mentioned embodiments or variant embodiments. According to the present variant embodiment, before the light emitting module LM is formed on the carrier substrate CR, a sacrificing layer SC may be formed on the carrier substrate CR at first. That is, the sacrificing layer SC may be disposed between the carrier substrate CR and the light emitting module LM. The sacrificing layer SC of the present variant embodiment may for example be detached from the carrier substrate CR through illuminating (such as laser) or heating, such that the sub-light emitting modules SM on the carrier substrate CR may be transferred to another carrier substrate or the target substrate TS. For example, the sacrificing layer SC may include photoresist materials (such as phenol-formaldehyde resin), epoxy resin or polyisoprene rubber), inorganic materials (such as silicon nitride, silicon oxide, silicon oxynitride or aluminum oxide), organic materials (such as polymethylmetacrylate (PMMA), benzocyclobutene (BCB), polyimide, polydimethylsiloxane (PDMS) or polyfluoroalkoxy (PFA)), other suitable materials or the combination of the above-mentioned materials, but not limited thereto. As shown in FIG. 24, during the cutting process of the light emitting module LM, the sacrificing layer SC may not be cut, but not limited thereto. That is, after the plurality of sub-light emitting modules SM are formed through the cutting process, the sacrificing layer SC may be a continuous layer on the carrier substrate CR. Therefore, curling of the sub-light emitting module SM caused by cutting the sacrificial layer SC may be reduced, thereby improving the yield of the sub-light emitting module SM. In some other embodiments, the sacrificing layer SC may be cut during the cutting process of the light emitting module. That is, the sacrificing layer SC may be divided into a plurality of portions respectively corresponding to different sub-light emitting modules SM. Therefore, when a specific sub-light emitting module SM is being transferred, the influence of the specific sub-light emitting module SM on other sub-light-emitting modules SM may be reduced. The sacrificing layer SC of the present variant embodiment may be applied to each of the embodiments or variant embodiments mentioned above for transferring the light emitting module LM or the sub-light emitting module SM.

According to the present variant embodiment, alight shielding layer LS3 may be disposed on a side of the carrier substrate CR opposite to the sub-light emitting modules SM before transferring the sub-light emitting modules SM, wherein the light shielding layer LS3 may be disposed corresponding to the cutting lines CT. For example, when the light emitting module LM includes a plurality of cutting lines CT extending and staggered along the direction X and the direction Y, the light shielding layer LS3 may be disposed corresponding to the cutting lines CT and may be array-shaped, but not limited thereto. In addition, as shown in FIG. 24, the cutting line CT may have a width W9, and the light shielding layer LS3 may have a width W10 in the present variant embodiment, wherein the width W9 may be greater than the width W10, but not limited thereto. That is, the width of the cutting line CT may be greater than the width of the light shielding layer LS3. In the present variant embodiment, when a sub-light emitting module SM is being transferred, the light shielding layer LS3 may reduce the influence of transferring process of the sub-light emitting module SM on other sub-light emitting modules SM. For example, as shown in FIG. 24, When the leftmost sub-light emitting module SM is to be transferred, the light L1 may be irradiated to remove a portion of the sacrificing layer SC corresponding to the leftmost sub-light emitting module SM. At this time, the light shielding layer LS3 on both sides of the leftmost sub-light emitting module SM in the normal direction (direction Z) of the carrier substrate CR may block the light L1, thereby reducing the possibility of the light L1 irradiating other portions of the sacrificing layer SC. Therefore, when the leftmost sub-light emitting module SM is being transferred, peeling of other sub-light emitting modules SM caused by the irradiation of the light L1 may be reduced. In addition, since the width W10 of the light shielding layer LS3 may be lower than the width W9 of the cutting line CT, the light may not be blocked by the light shielding layer LS3 and may be irradiated to the sacrificing layer SC corresponding to the sub-light emitting module SM. Therefore, the possibility that the sacrificing layer SC corresponding to the sub-light emitting module SM is not removed may be reduced, thereby improving the transferring process of the sub-light emitting module SM. The material of the light shielding layer LS3 may refer to the light shielding layer LS2 mentioned above, and will not be redundantly described.

Referring to FIG. 25, FIG. 25 schematically illustrates an electronic device according to a variant embodiment of the third embodiment of the present disclosure. In order to simplify the figure, FIG. 25 only shows the light emitting unit LU and the encapsulation layer EN of the sub-light emitting module SM, wherein the encapsulation layer EN may include the protection layer PL, the cover layer CP or other layers located above the light emitting unit LU in the above-mentioned embodiments, but not limited thereto. In addition, although the structure shown in FIG. 25 includes the sacrificing layer SC, the present variant embodiment is not limited thereto. According to the present variant embodiment, at least a portion of the encapsulation layer EN of the light emitting module LM may be removed to form at least one recess RS before the cutting process of the light emitting module LM is performed. As shown in FIG. 25, after the recess RS is formed, the sub-light emitting modules SM may for example be defined through the recess RS. Then, a first inorganic layer IOL1, a first organic layer OL1 and a second inorganic layer IOL2 may be formed on the light emitting module LM and the recess RS in sequence to forma stacked structure covering the light emitting module LM and the recess RS. After that, the cutting process may be performed along the cutting lines (not shown) to divide the light emitting module LM into the sub-light emitting modules SM, wherein the cutting lines may for example correspond to the recess RS, but not limited thereto. The sub-light emitting module SM formed through the above-mentioned method may be covered by the first inorganic layer IOL1, the first organic layer OL1 and the second inorganic layer IOL2. Therefore, the first inorganic layer IOL1, the first organic layer OL1 and the second inorganic layer IOL2 may provide the sub-light emitting module SM with the effect of waterproof and anti-oxygen. In some embodiments, one or more inorganic layers and insulating layers may be disposed on the light emitting module LM and the recess RS, but the present disclosure is not limited thereto.

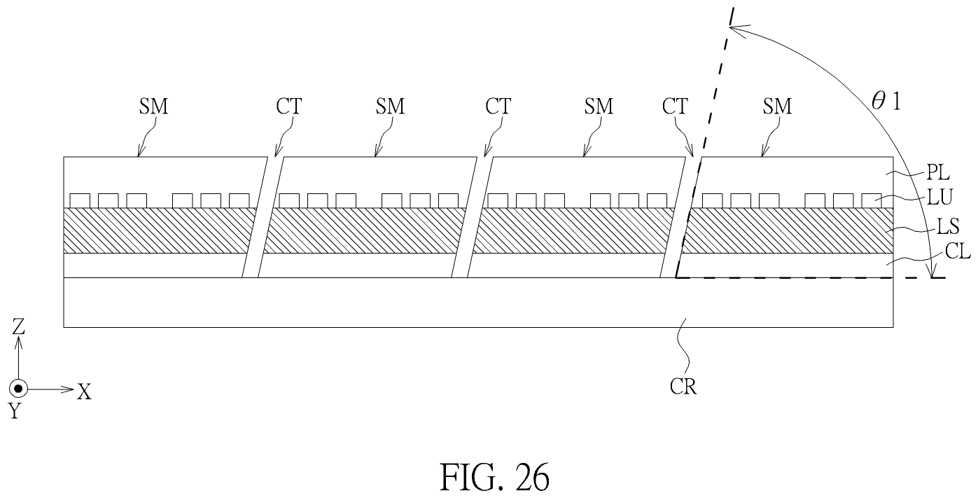

Referring to FIG. 26, FIG. 26 schematically illustrates an electronic device according to a variant embodiment of the third embodiment of the present disclosure. According to the cross-section view of the structure of the present variant embodiment, in the cutting process of the light emitting module LM, the extending direction of the cutting line CT may not be parallel to the normal direction (the direction Z) of the carrier substrate CR. In detail, as shown in FIG. 26, an included angle θ1 may be included between the extending direction of the cutting lines CT and the surface of the carrier substrate CR, wherein the included angle θ1 may be the acute angle between the extending direction of the cutting lines CT and the surface of the carrier substrate CR (that is, θ1<90°). In the present variant embodiment, the included angle θ1 may for example range from 45 degrees to 80 degrees (that is, 45°≤θ1≤80°, but not limited thereto. By making the included angle θ1 between the cutting line CT and the surface of the carrier substrate CR in the above-mentioned range, when the sub-light emitting module SM of the present variant embodiment is applied to tiled display devices, the condition that the circuit layer CL is perceived by the user due to the reflection of light entering the gap may be reduced, thereby reducing the sense of seam of the tiled display devices.

In summary, a manufacturing method of an electronic device is provided by the present disclosure, wherein the patterned light absorbing layer of the electronic device formed through the manufacturing method of the present disclosure may be located between the circuit layer and the light emitting unit. Therefore, the patterned light absorbing layer may reduce the non-display light generated by the reflection of ambient light by the circuit layer, thereby improving the contrast of the electronic device. In addition, according to the manufacturing method of the present disclosure, the light emitting module may be divided into the sub-light emitting modules on the carrier substrate at first, and then the sub-light emitting modules may be transferred to the target substrate to form the electronic device, thereby reducing the difficulty of the transferring process.

Those skilled in the art will readily observe that numerous modifications and alterations of the device and method may be made while retaining the teachings of the disclosure. Accordingly, the above disclosure should be construed as limited only by the metes and bounds of the appended claims.

What is claimed is:

1. A method for manufacturing an electronic device, comprising:
providing a carrier substrate;
forming a light emitting module on the carrier substrate, which comprises:
transferring a light emitting unit to the carrier substrate;
forming a circuit layer on the carrier substrate; and
forming a patterned light absorbing layer on the carrier substrate, the patterned light absorbing layer comprising an opening through which the light emitting unit is electrically connected to the circuit layer; and
transferring the light emitting module to a target substrate.

2. The method of claim 1, wherein the circuit layer is formed on the carrier substrate before the light emitting unit is transferred to the carrier substrate.

3. The method of claim 1, wherein the circuit layer is formed on the carrier substrate after the light emitting unit is transferred to the carrier substrate.

4. The method of claim 3, further comprising transferring the light emitting module to another carrier substrate before transferring the light emitting module to the target substrate.

5. The method of claim 1, wherein the patterned light absorbing layer is formed on the carrier substrate by a printing process.

6. The method of claim 1, wherein the patterned light absorbing layer is formed on the carrier substrate by a photolithography process.

7. The method of claim 1, wherein the target substrate is configured to drive the light emitting unit.

8. A method for manufacturing an electronic device, comprising:
providing a carrier substrate;
forming a light emitting module on the carrier substrate, which comprises:
transferring a plurality of light emitting units to the carrier substrate; and
forming a circuit layer on the carrier substrate;
dividing the light emitting module into a plurality of sub-light emitting modules on the carrier substrate; and
transferring at least one of the plurality of sub-light emitting modules to a target substrate after dividing the light emitting module into the plurality of sub-light emitting modules on the carrier substrate.

9. The method of claim 8, further comprising providing a supporting substrate on the at least one of the plurality of sub-light emitting modules and transferring the at least one of the plurality of sub-light emitting modules with the supporting substrate.

10. The method of claim 9, further comprising reversing the at least one of the plurality of sub-light emitting modules with the supporting substrate.

11. The method of claim 8, further comprising providing a supporting substrate on the light emitting module before dividing the light emitting module into the plurality of sub-light emitting modules on the carrier substrate and transferring the at least one of the plurality of sub-light emitting modules with the supporting substrate.

12. The method of claim 8, further comprising forming a sacrificial layer on the carrier substrate before forming the light emitting module on the carrier substrate, wherein the sacrificial layer is disposed between the carrier substrate and the light emitting module.
